(19) United States
(12) Patent Application Publication
(10) Pub. No.: US 2025/0041987 A1
(43) Pub. Date: Feb. 6, 2025

(54) POLISHING APPARATUS

(71) Applicant: EBARA CORPORATION, Tokyo (JP)

(72) Inventors: Masaki KINOSHITA, Tokyo (JP); Yoichi SHIOKAWA, Tokyo (JP); Keita TANOUE, Tokyo (JP)

(21) Appl. No.: 18/785,044

(22) Filed: Jul. 26, 2024

(30) Foreign Application Priority Data
Aug. 4, 2023 (JP) 2023-127806

(51) Int. Cl. B24B 37/013

(52) U.S. Cl. CPC B24B 37/013

(57) ABSTRACT

A polishing apparatus includes: a polishing table configured to support a polishing pad having a through-hole; an optical film-thickness measuring system having an optical sensor head mounted to the polishing table; a transparent-liquid inlet passage configured to supply a transparent liquid to the through-hole; and a light-emitting-side transparent-liquid outlet passage and a light-receiving-side transparent-liquid outlet passage communicating with the through-hole. The optical sensor head has a light-emitting surface configured to emit light obliquely upward and a light-receiving surface configured to receive reflected light from the workpiece, and the light-emitting surface faces the light-emitting-side transparent-liquid outlet passage, and the light-receiving surface faces the light-receiving-side transparent-liquid outlet passage.

### CROSS REFERENCE TO RELATED APPLICATION

This document claims priority to Japanese Patent Application No. 2023-127806 filed Aug. 4, 2023, the entire contents of which are hereby incorporated by reference.

### BACKGROUND

A chemical mechanical polishing (CMP) apparatus configured to polish a surface of a workpiece, such as a wafer, is used in a manufacturing process of semiconductor devices. The CMP apparatus includes a polishing table to which a polishing pad is attached, and a polishing head configured to press the workpiece against a polishing surface of the polishing pad. The CMP apparatus presses the workpiece against the polishing surface of the polishing pad by the polishing head while supplying a polishing liquid (e.g., slurry) onto the polishing pad to thereby place the surface of the workpiece in sliding contact with the polishing surface of the polishing pad. The surface of the workpiece is polished by a chemical action of the polishing liquid and mechanical action(s) of abrasive grains contained in the polishing liquid and/or the polishing pad.

Polishing of the workpiece is terminated when a thickness of a film (e.g., a dielectric film, a silicon layer, etc.), constituting the surface of the workpiece, has reached a target film thickness. The polishing apparatus includes an optical film-thickness measuring system configured to measure the film thickness of the workpiece. The optical film-thickness measuring system is configured to direct light onto the workpiece and receive reflected light from the workpiece by an optical sensor head disposed in the polishing table, produce a spectrum of the reflected light from intensity of the reflected light, and determine the film thickness of the workpiece based on the spectrum of the reflected light.

In order to stabilize the film thickness measurement by the optical film-thickness measuring system, it is necessary to keep the light path clean. For example, Patent Document 1 describes a method of limiting the intrusion of polishing liquid and polishing debris by filling the light path with a transparent liquid.

However, the abrasive grains contained in the polishing liquid and the polishing debris of the workpiece usually have a larger specific gravity than the transparent liquid. As a result, the abrasive grains and the polishing debris may adhere to the optical sensor head. When the abrasive grains and the polishing debris adhere to the optical sensor head, a measured value of intensity of the reflected light from the workpiece decreases. As a result, the optical film-thickness measuring system may not accurately measure the film thickness.

### SUMMARY

Therefore, there is provided a polishing apparatus capable of preventing abrasive grains in a polishing liquid and polishing debris of a workpiece from adhering to an optical sensor head and capable of improving a measuring accuracy of a film thickness of a workpiece.

Embodiments, which will be described below, relate to a technique of polishing a workpiece, such as a wafer, an interconnect substrate, a quadrangular substrate, and more particularly to a technique of directing light to the workpiece through a through-hole of a polishing pad for polishing the workpiece and measuring a film thickness of the workpiece based on spectrum of reflected light from the workpiece.

In an embodiment, there is provided a polishing apparatus comprising: a polishing table configured to support a polishing pad having a through-hole; a polishing head configured to press a workpiece against the polishing pad; an optical film-thickness measuring system having an optical sensor head mounted to the polishing table; a transparent-liquid inlet passage configured to supply a transparent liquid to the through-hole; and a light-emitting-side transparent-liquid outlet passage and a light-receiving-side transparent-liquid outlet passage communicating with the through-hole, wherein the optical sensor head has a light-emitting surface configured to emit light obliquely upward and a light-receiving surface configured to receive reflected light from the workpiece, and the light-emitting surface faces the light-emitting-side transparent-liquid outlet passage, and the light-receiving surface faces the light-receiving-side transparent-liquid outlet passage.

In an embodiment, the light-emitting surface and the light-receiving surface face obliquely upward.

In an embodiment, the light-emitting surface is located in the light-emitting-side transparent-liquid outlet passage, and the light-receiving surface is located in the light-receiving-side transparent-liquid outlet passage.

In an embodiment, the transparent-liquid inlet passage is located between the light-emitting-side transparent-liquid outlet passage and the light-receiving-side transparent-liquid outlet passage.

In an embodiment, the light-emitting-side transparent-liquid outlet passage and the light-receiving-side transparent-liquid outlet passage are arranged symmetrically with respect to the transparent-liquid inlet passage.

In an embodiment, the transparent-liquid inlet passage is coupled to a transparent-liquid supply source which is a pure-water supply source or a chemical-liquid supply source.

In an embodiment, the polishing apparatus further comprises an ultrasonic vibrator configured to apply ultrasonic waves to the transparent liquid flowing through the transparent-liquid inlet passage.

In an embodiment, the polishing apparatus further comprises: a flow-rate regulation valve coupled to the transparent-liquid inlet passage; and an operation controller configured to control operation of the flow-rate regulation valve, the operation controller being configured to: instruct the flow-rate regulation valve to supply the transparent liquid to the through-hole at a first flow rate when the workpiece is located over the through-hole during polishing of the workpiece; and instruct the flow-rate regulation valve to supply the transparent liquid to the through-hole at a second flow rate lower than the first flow rate when the workpiece is not located over the through-hole during polishing of the workpiece.

The transparent liquid supplied from the transparent-liquid inlet passage into the through-hole of the polishing pad forms a flow toward the light-emitting-side transparent-liquid outlet passage and the light-receiving-side transparent-liquid outlet passage. The light-emitting surface and the light-receiving surface of the optical sensor head face the light-emitting-side transparent-liquid outlet passage and the light-receiving-side transparent-liquid outlet passage, respectively, so that the flow of the transparent liquid in the light-emitting-side transparent-liquid outlet passage and the light-receiving-side transparent-liquid outlet passage contacts the light-emitting surface and the light-receiving surface of the optical sensor head, and can clean the light-emitting surface and the light-receiving surface. The optical sensor head directs the light to the workpiece and receives the reflected light from the workpiece, and the optical film-thickness measuring system can accurately measure the film thickness of the workpiece based on the intensity of the reflected light from the workpiece.

### BRIEF DESCRIPTION OF THE DRAWINGS

FIG. 1 is a schematic diagram showing an embodiment of a polishing apparatus;

FIG. 2 is a cross-sectional view showing a detailed configuration of an optical film-thickness measuring system;

FIG. 3 is an enlarged cross-sectional view showing an embodiment of an optical sensor head, a transparent-liquid inlet passage, a light-emitting-side transparent-liquid outlet passage, and a light-receiving-side transparent-liquid outlet passage;

FIG. 4 is an enlarged cross-sectional view showing another embodiment of the polishing apparatus; and

FIG. 5 is an enlarged cross-sectional view showing still another embodiment of the polishing apparatus.

### DESCRIPTION OF EMBODIMENTS

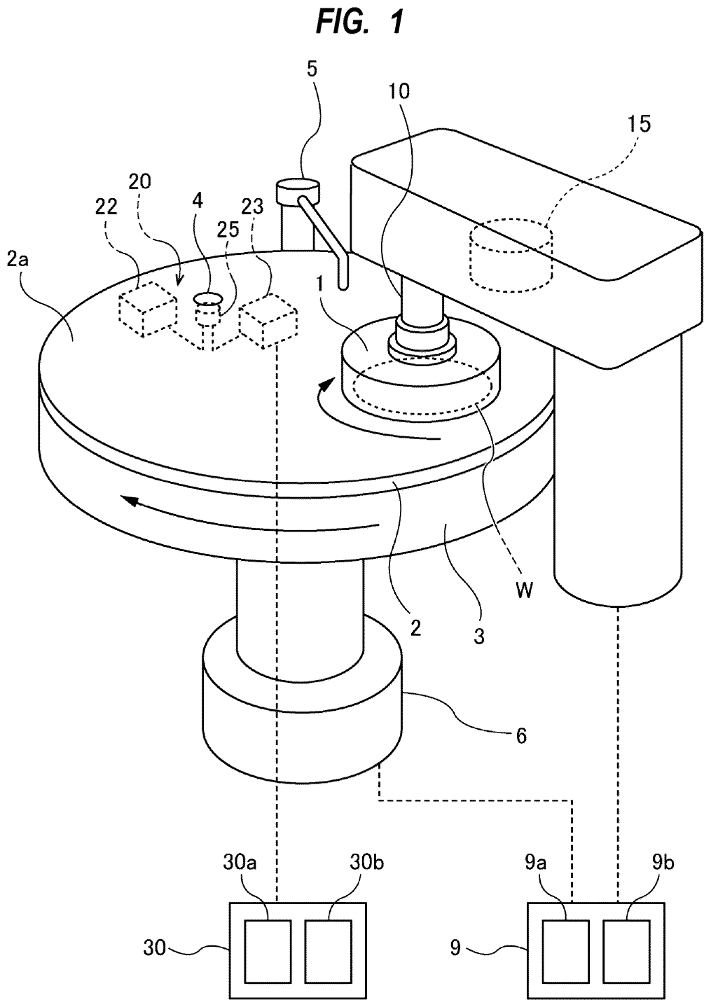

Embodiments will now be described with reference to the drawings. FIG. 1 is a schematic diagram showing an embodiment of a polishing apparatus. As shown in FIG. 1, the polishing apparatus includes a polishing pad 2 having a through-hole 4 formed therein, a polishing table 3 configured to support the polishing pad 2, a polishing head 1 configured to press a workpiece W against the polishing pad 2, a table motor 6 configured to rotate the polishing table 3, a polishing-liquid supply nozzle 5 configured to supply a polishing liquid, such as slurry, onto the polishing pad 2, and an operation controller 9 configured to control operations of the polishing apparatus.

The polishing pad 2 has an upper surface constituting a polishing surface 2a for polishing the workpiece W. The through-hole 4 extends through the polishing pad 2. The workpiece W has a film that constitutes its surface. Examples of the workpiece W to be polished include a wafer, an interconnect substrate, and a quadrangular substrate used in manufacturing of semiconductor devices.

The polishing head 1 is coupled to a head shaft 10, and the head shaft 10 is coupled to a polishing-head rotating device 15. The polishing-head rotating device 15 is configured to rotate the polishing head 1 together with the head shaft 10 in a direction indicated by an arrow. The configuration of the polishing-head rotating device 15 is not particularly limited. In an example, the polishing-head rotating device 15 includes an electric motor, a belt, and pulleys. The polishing table 3 is coupled to the table motor 6, and the table motor 6 is configured to rotate the polishing table 3 and the polishing pad 2 in a direction indicated by an arrow. The polishing head 1, the polishing-head rotating device 15, and the table motor 6 are electrically coupled to the operation controller 9.

Polishing of the workpiece W is performed as follows. The polishing liquid is supplied from the polishing-liquid supply nozzle 5 onto the polishing surface 2a of the polishing pad 2 on the polishing table 3, while the table motor 6 and the polishing-head rotating device 15 rotate the polishing table 3 and the polishing head 1 in the directions indicated by the arrows in FIG. 1. The workpiece W is pressed against the polishing surface 2a of the polishing pad 2 by the polishing head 1 in the presence of the polishing liquid on the polishing pad 2, while the workpiece W is being rotated by the polishing head 1. The surface of the workpiece W is polished by a chemical action of the polishing liquid and mechanical action(s) of abrasive grains contained in the polishing liquid and/or the polishing pad 2.

The operation controller 9 includes a memory 9a storing programs therein, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

The polishing apparatus includes an optical film-thickness measuring system 20 for measuring a film thickness of the workpiece W. The optical film-thickness measuring system 20 includes a light source 22 configured to emit light, an optical sensor head 25 configured to irradiate the workpiece W with the light from the light source 22 and receive reflected light from the workpiece W, a spectrometer 23 coupled to the optical sensor head 25, and a spectrum processor 30 configured to determine a film thickness of the workpiece W based on a spectrum of the reflected light from the workpiece W. The optical sensor head 25 is mounted to the polishing table 3 and rotates together with the polishing table 3.

The spectrum processor 30 includes a memory 30a storing programs therein, and an arithmetic device 30b configured to perform arithmetic operations according to instructions contained in the programs. The spectrum processor 30 is composed of at least one computer. The memory 30a includes a main memory, such as a random-access memory (RAM), and an auxiliary memory, such as a hard disk drive (HDD) or a solid state drive (SSD). Examples of the arithmetic device 30b include a CPU (central processing unit) and a GPU (graphic processing unit). However, the specific configuration of the spectrum processor 30 is not limited to these examples.

Each of the operation controller 9 and the spectrum processor 30 may be composed of a plurality of computers. For example, each of the operation controller 9 and the spectrum processor 30 may be configured of a combination of an edge server and a cloud server. In one embodiment, the operation controller 9 and the spectrum processor 30 may be comprised of one computer.

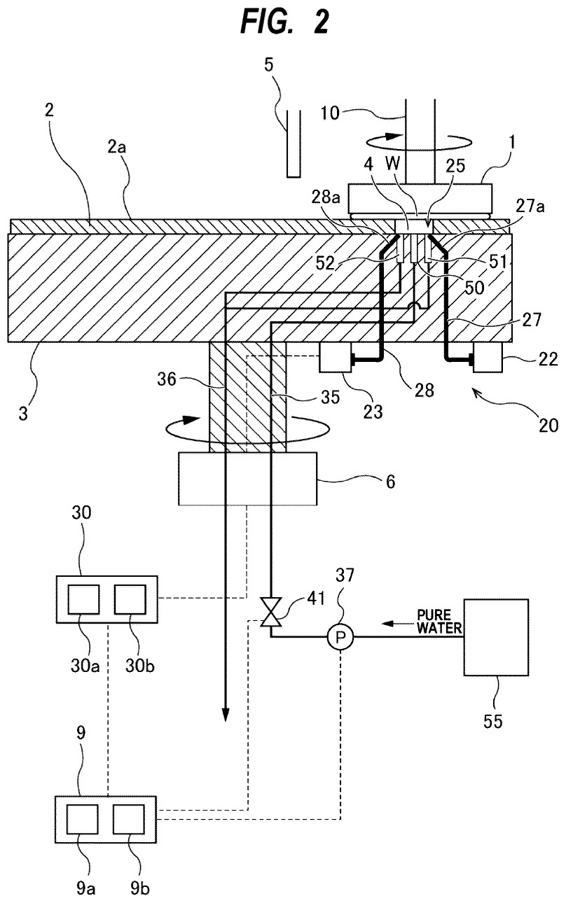

FIG. 2 is a cross-sectional view showing a detailed configuration of the optical film-thickness measuring system 20. The optical sensor head 25 is disposed in the polishing table 3, and the light source 22 and the spectrometer 23 are attached to the polishing table 3. The optical sensor head 25, the light source 22, and the spectrometer 23 rotate together with the polishing table 3 and the polishing pad 2. A position of the optical sensor head 25 is such that the optical sensor head 25 moves across the surface of the workpiece W on the polishing pad 2 each time the polishing table 3 and the polishing pad 2 make one rotation. The optical sensor head 25 is coupled to the light source 22 and the spectrometer 23, and the spectrometer 23 is coupled to the spectrum processor 30.

The optical film-thickness measuring system 20 includes a light-emitting optical fiber cable 27 configured to direct the light, emitted from the light source 22, onto the surface of the workpiece W, and a light-receiving optical fiber cable 28 configured to receive the reflected light from the workpiece W and transmit the reflected light to the spectrometer 23. A distal end 27a of the light-emitting optical fiber cable 27 and a distal end 28a of the light-receiving optical fiber cable 28 constitute the optical sensor head 25 that directs the light to the surface of the workpiece W and receives the reflected light from the workpiece W. Other end of the light-emitting optical fiber cable 27 is coupled to the light source 22, and other end of the light-receiving optical fiber cable 28 is coupled to the spectrometer 23. The spectrometer 23 is configured to resolve the reflected light from the workpiece W according to wavelength of the reflected light and measure intensities of the reflected light over a predetermined wavelength range.

The optical sensor head 25 that is constituted by the distal end 27a of the light-emitting optical fiber cable 27 and the distal end 28a of the light-receiving optical fiber cable 28 is located below the through-hole 4 of the polishing pad 2 and face the through-hole 4. The light emitted by the light source 22 travels through the light-emitting optical fiber cable 27, and is emitted from the optical sensor head 25 through the through-hole 4 to the workpiece W. The reflected light from the workpiece W passes through the through-hole 4 and is received by the optical sensor head 25. The reflected light is transmitted to the spectrometer 23 through the light-receiving optical fiber cable 28. The spectrometer 23 resolves the reflected light according to its wavelengths and generates intensity measurement data of the reflected light by measuring the intensity of the reflected light at each of the wavelengths. The intensity measurement data of the reflected light is transmitted from the spectrometer 23 to the spectrum processor 30.

The spectrum processor 30 is configured to generate a spectrum of the reflected light from the workpiece W from the intensity measurement data of the reflected light. The spectrum of the reflected light is expressed as a line graph (i.e., a spectral waveform) representing a relationship between wavelength and intensity of the reflected light. The intensity of the reflected light can also be expressed as a relative value, such as reflectance or relative reflectance.

The spectrum processor 30 is configured to determine the film thickness of the workpiece W based on the spectrum of the reflected light. A known method may be used to determine the film thickness of the workpiece W based on the spectrum. For example, the spectrum processor 30 determines a reference spectrum that is closest in shape to the spectrum of the reflected light from a reference spectrum library, and determines a film thickness associated with the determined reference spectrum. In another example, the spectrum processor 30 performs a Fourier transform on the spectrum of the reflected light, and determines a film thickness from a frequency spectrum obtained.

The polishing table 3 has a transparent-liquid inlet passage 50, a light-emitting-side transparent-liquid outlet passage 51, and a light-receiving-side transparent-liquid outlet passage 52, which are in fluid communication with the through-hole 4. The transparent-liquid inlet passage 50, the light-emitting-side transparent-liquid outlet passage 51, and the light-receiving-side transparent-liquid outlet passage 52 are provided in the polishing table 3 and rotate together with the polishing table 3. The polishing apparatus 1 includes a transparent-liquid supply line 35 coupled to the transparent-liquid inlet passage 50, a transparent-liquid discharge line 36 coupled to the light-emitting-side transparent-liquid outlet passage 51 and the light-receiving-side transparent-liquid outlet passage 52, and a supply pump 37 and a flow-rate regulation valve 41 coupled to the transparent-liquid supply line 35.

One end of the transparent-liquid supply line 35 is coupled to the transparent-liquid inlet passage 50, and other end is coupled to a transparent-liquid supply source 55. The transparent-liquid inlet passage 50 may be configured integrally with the transparent-liquid supply line 35. An example of the transparent-liquid supply source 55 is a pure-water supply source that supplies pure water as the transparent liquid. The pure water, which is the transparent liquid, is supplied into the through-hole 4 of the polishing pad 2 through the transparent-liquid supply line 35 and the transparent-liquid inlet passage 50.

The pure water that has been supplied into the through-hole 4 of the polishing pad 2 is discharged from the through-hole 4 through the light-emitting-side transparent-liquid outlet passage 51 and the light-receiving-side transparent-liquid outlet passage 52, and is further discharged through the transparent-liquid discharge line 36. The light-emitting-side transparent-liquid outlet passage 51 and the light-receiving-side transparent-liquid outlet passage 52 may be configured integrally with the transparent-liquid discharge line 36.

In one embodiment, the transparent liquid may be a liquid other than pure water as long as it does not hinder transmission of the light. The supply pump 37 is configured to pressurize the pure water flowing through the transparent-liquid supply line 35. The pure water pressurized by the supply pump 37 is supplied to the through-hole 4 through the transparent-liquid supply line 35 and the transparent-liquid inlet passage 50.

The flow-rate regulation valve 41 is an actuator-driven valve, such as an electric valve, an electromagnetic valve, or an air-operated valve. The flow-rate regulation valve 41 is electrically coupled to the operation controller 9, and operation of the flow-rate regulation valve 41 is controlled by the operation controller 9.

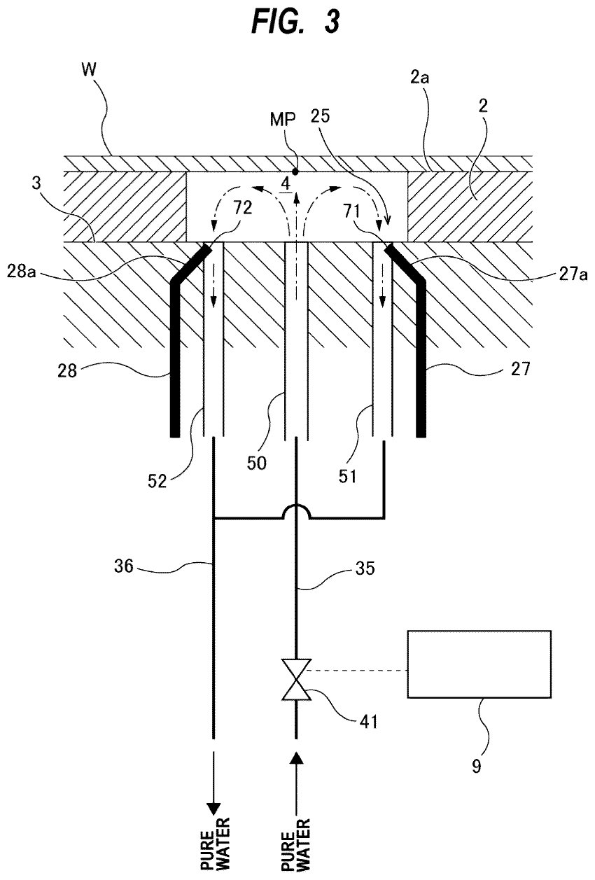

FIG. 3 is an enlarged cross-sectional view showing one embodiment of the optical sensor head 25, the transparent-liquid inlet passage 50, the light-emitting-side transparent-liquid outlet passage 51, and the light-receiving-side transparent-liquid outlet passage 52. As shown in FIG. 3, the optical sensor head 25, which is composed of the end 27a of the light-emitting optical fiber cable 27 and the end 28a of the light-receiving optical fiber cable 28, is located below the through-hole 4 of the polishing pad 2. The end 27a of the light-emitting optical fiber cable 27 is inclined upward, and the end 28a of the light-receiving optical fiber cable 28 is also inclined upward at the same angle.

The optical sensor head 25 has a light-emitting surface 71 configured to emit the light and a light-receiving surface 72 configured to receive the reflected light from the workpiece W. In this embodiment, the light-emitting surface 71 is composed of an end surface of the light-emitting optical fiber cable 27, and the light-receiving surface 72 is composed of an end surface of the light-receiving optical fiber cable 28. In one embodiment, the light-emitting surface 71 and the light-receiving surface 72 may be constituted of optical elements, such as lens, glass, or mirror, that face the end surfaces of the light-emitting optical fiber cable 27 and the light-receiving optical fiber cable 28.

The light-emitting surface 71 and the light-receiving surface 72 face obliquely upward at the same angle. More specifically, the light-emitting surface 71 and the light-receiving surface 72 point at the same measurement point MP on the surface of the workpiece W on the polishing pad 2. Therefore, the light-emitting surface 71 of the optical sensor head 25 emits the light obliquely upward and directs the light to the measurement point MP on the surface of the workpiece W. The reflected light from the measurement point MP travels obliquely downward toward the light-receiving surface 72 of the optical sensor head 25 and is incident on the light-receiving surface 72.

Upper ends of the transparent-liquid inlet passage 50, the light-emitting-side transparent-liquid outlet passage 51, and the light-receiving-side transparent-liquid outlet passage 52 open in the upper surface of the polishing table 3 and communicate with the through-hole 4. The transparent-liquid inlet passage 50, the light-emitting-side transparent-liquid outlet passage 51, and the light-receiving-side transparent-liquid outlet passage 52 extend downward from the upper surface of the polishing table 3. The transparent-liquid inlet passage 50 is coupled to the transparent-liquid supply line 35. The light-emitting-side transparent-liquid outlet passage 51 and the light-receiving-side transparent-liquid outlet passage 52 are coupled to the transparent-liquid discharge line 36.

During polishing of the workpiece W, the through-hole 4 is filled with the pure water, which is the transparent liquid. The light emitted from the optical sensor head 25, composed of the end 27a of the light-emitting optical fiber cable 27 and the end 28a of the light-receiving optical fiber cable 28, passes through the pure water filling the through-hole 4 and irradiates the workpiece W on the polishing pad 2. The reflected light from the workpiece W passes through the pure water filling the through-hole 4 and is received by the optical sensor head 25.

The end 27a of the light-emitting optical fiber cable 27 constituting the optical sensor head 25 is coupled to the light-emitting-side transparent-liquid outlet passage 51. The light-emitting surface 71 of the optical sensor head 25 faces the light-emitting-side transparent-liquid outlet passage 51. The end 28a of the light-receiving optical fiber cable 28 constituting the optical sensor head 25 is coupled to the light-receiving-side transparent-liquid outlet passage 52. The light-receiving surface 72 of the optical sensor head 25 faces the light-receiving-side transparent-liquid outlet passage 52.

The transparent-liquid inlet passage 50 is located directly under the measurement point MP of the workpiece W (i.e., the point irradiated with the light from the optical sensor head 25). The transparent-liquid inlet passage 50 is located between the light-emitting-side transparent-liquid outlet passage 51 and the light-receiving-side transparent-liquid outlet passage 52, and the pure water as the transparent liquid flows upward from the transparent-liquid inlet passage 50. The light-emitting-side transparent-liquid outlet passage 51 and the light-receiving-side transparent-liquid outlet passage 52 are disposed symmetrically with respect to the transparent-liquid inlet passage 50.

The pure water, which is the transparent liquid, flows from the transparent-liquid inlet passage 50 into the through-hole 4 and flows toward the measurement point MP on the surface of the workpiece W on the polishing pad 2. The pure water changes its direction in the through-hole 4 and flows into the light-emitting-side transparent-liquid outlet passage 51 and the light-receiving-side transparent-liquid outlet passage 52. The flows of the pure water in the light-emitting-side transparent-liquid outlet passage 51 and the light-receiving-side transparent-liquid outlet passage 52 contact the light-emitting surface 71 and the light-receiving surface 72 of the optical sensor head 25, and can therefore prevent the abrasive grains contained in the polishing liquid and the polishing debris of the workpiece W from adhering to the light-emitting surface 71 and the light-receiving surface 72. Therefore, the light-emitting surface 71 and the light-receiving surface 72 of the optical sensor head 25 can be kept clean.

The light-receiving surface 72 of the optical sensor head 25 receives the reflected light from the measurement point MP of the workpiece W. The optical film-thickness measuring system 20 can accurately measure the film thickness at the measurement point MP of the workpiece W based on the intensity of the reflected light from the workpiece W.

In the embodiment shown in FIG. 3, in order to improve the cleaning effect of the light-emitting surface 71 and the light-receiving surface 72 of the optical sensor head 25 by the flow of pure water, the end 27a of the light-emitting optical fiber cable 27 protrudes into the light-emitting-side transparent-liquid outlet passage 51, so that the light-emitting surface 71 of the optical sensor head 25 is located in the light-emitting-side transparent-liquid outlet passage 51. Similarly, the end 28a of the light-receiving optical fiber cable 28 protrudes into the light-receiving-side transparent-liquid outlet passage 52, so that the light-receiving surface 72 of the optical sensor head 25 is located in the light-receiving-side transparent-liquid outlet passage 52. The pure water forms fast flows in the light-emitting-side transparent-liquid outlet passage 51 and the light-receiving-side transparent-liquid outlet passage 52, and these flows of the pure water can maintain the cleanliness of the light-emitting surface 71 and the light-receiving surface 72 of the optical sensor head 25.

During polishing of the workpiece W, the flow-rate regulation valve 41 is opened, so that the pure water as the transparent liquid is supplied into the through-hole 4 through the transparent-liquid supply line 35 and the transparent-liquid inlet passage 50. During polishing of the workpiece W, the polishing pad 2 rotates together with the polishing table 3, while the workpiece W held by the polishing head 1 does not rotate together with the polishing table 3. Therefore, there are times when the workpiece W is located over the through-hole 4 and times when the workpiece W is not located over the through-hole 4. In other words, the workpiece W periodically covers the through-hole 4 while the polishing pad 2 and the polishing table 3 rotate.

The flow-rate regulation valve 41 is coupled to the transparent-liquid inlet passage 50 via the transparent-liquid supply line 35. The flow-rate regulation valve 41 can regulate the flow rate of the pure water supplied into the through-hole 4. The operation of the flow-rate regulation valve 41 is controlled by the operation controller 9. In one embodiment, the flow rate of the pure water supplied into the through-hole 4 is maintained constant by the flow-rate regulation valve 41 during polishing of the workpiece W. In another embodiment, the operation controller 9 is configured to instruct the flow-rate regulation valve 41 to supply the pure water to the through-hole 4 at a first flow rate when the workpiece W is located over the through-hole 4 during polishing of the workpiece W, and to instruct the flow-rate regulation valve 41 to supply the pure water to the through-hole 4 at a second flow rate lower than the first flow rate when the workpiece W is not located over the through-hole 4 during polishing of the workpiece W.

When the workpiece W is located over the through-hole 4, the through-hole 4 is closed by the workpiece W. Therefore, by supplying the pure water to the through-hole 4 at the first flow rate that is higher than the second flow rate, fast flows of pure water can be formed in the light-emitting-side transparent-liquid outlet passage 51 and the light-receiving-side transparent-liquid outlet passage 52. These fast flows of pure water can improve the cleaning effect of the light-emitting surface 71 and the light-receiving surface 72 of the optical sensor head 25.

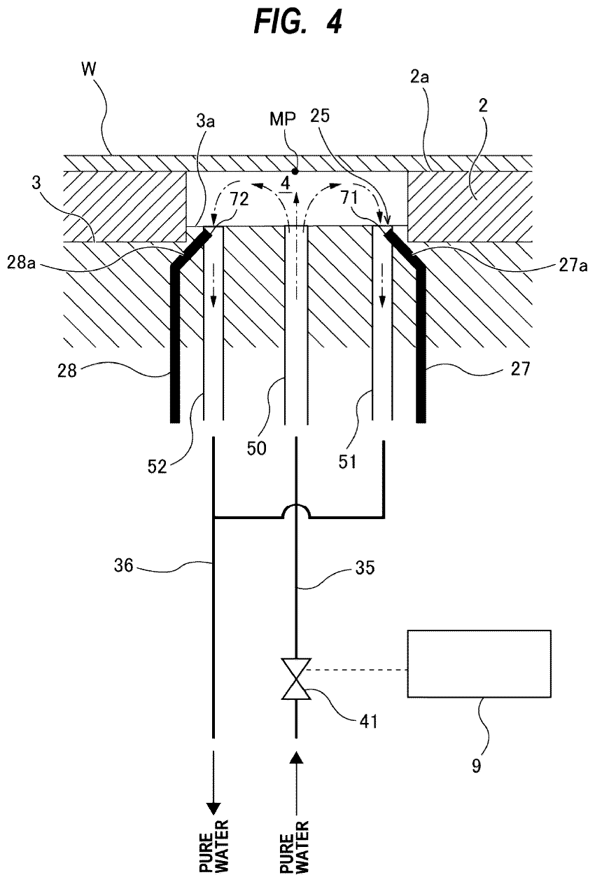

In the embodiment shown in FIG. 3, the light-emitting surface 71 and the light-receiving surface 72 of the optical sensor head 25 are located lower than the polishing pad 2. In one embodiment, as shown in FIG. 4, the polishing table 3 may have a protrusion 3a located in the through-hole 4 of the polishing pad 2. The light-emitting surface 71 and the light-receiving surface 72 of the optical sensor head 25, the upper ends of the transparent-liquid inlet passage 50, the light-emitting-side transparent-liquid outlet passage 51, and the upper ends of the light-receiving-side transparent-liquid outlet passage 52 may be located in the protrusion 3a. The protrusion 3a protrudes upward and fits into a lower part of the through-hole 4. The transparent-liquid inlet passage 50, the light-emitting-side transparent-liquid outlet passage 51, and the light-receiving-side transparent-liquid outlet passage 52 are open in an upper surface of the protrusion 3a.

The embodiment shown in FIG. 4 is the same as the embodiment shown in FIG. 3 in that the light-emitting surface 71 and the light-receiving surface 72 of the optical sensor head 25 are located in the light-emitting-side transparent-liquid outlet passage 51 and the light-receiving-side transparent-liquid outlet passage 52, but differs in that the light-emitting surface 71 and the light-receiving surface 72 of the optical sensor head 25 are located in the polishing pad 2.

In the embodiment shown in FIG. 4, the flows of pure water in the light-emitting-side transparent-liquid outlet passage 51 and the light-receiving-side transparent-liquid outlet passage 52 come into contact with the light-emitting surface 71 and the light-receiving surface 72 of the optical sensor head 25, and can prevent the abrasive grains contained in the polishing liquid and the polishing debris of the workpiece W from adhering to the light-emitting surface 71 and the light-receiving surface 72. Therefore, the light-emitting surface 71 and the light-receiving surface 72 of the optical sensor head 25 can be kept clean.

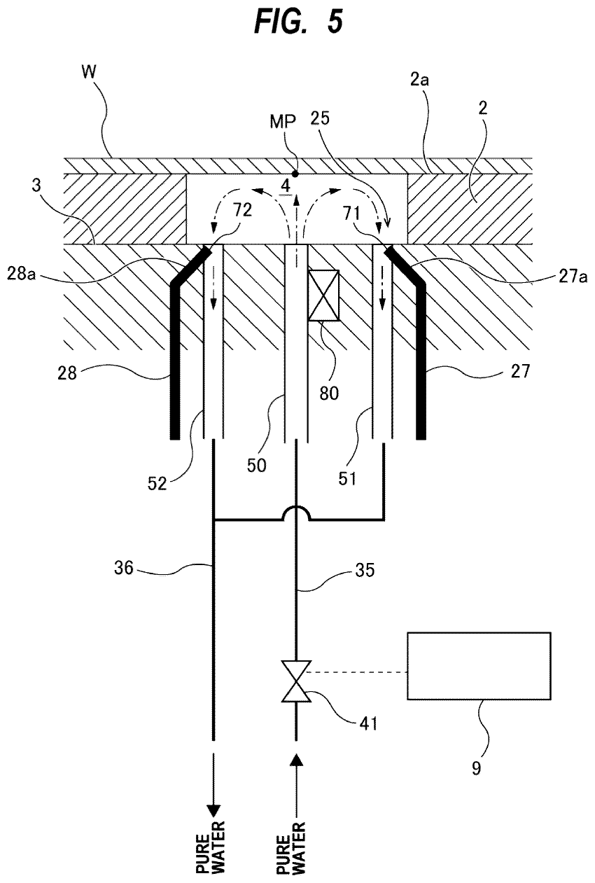

FIG. 5 is an enlarged cross-sectional view showing still another embodiment of the polishing apparatus. Configurations and operations of this embodiment, which will not be specifically described, are the same as those of the embodiment described with reference to FIGS. 1 to 3, and therefore duplicated descriptions will be omitted.

In the embodiment shown in FIG. 5, the polishing apparatus includes an ultrasonic transducer 80 configured to apply ultrasonic waves to the pure water, which serves as the transparent liquid, flowing through the transparent-liquid inlet passage 50. The ultrasonic transducer 80 is installed in the polishing table 3 and is adjacent to the transparent-liquid inlet passage 50.

According to this embodiment, the pure water to which ultrasonic waves have been applied by the ultrasonic vibrator 80 fills the through-hole 4, and then flows through the light-emitting-side transparent-liquid outlet passage 51 and the light-receiving-side transparent-liquid outlet passage 52, thereby effectively cleaning the light-emitting surface 71 and the light-receiving surface 72 of the optical sensor head 25. The ultrasonic vibrator 80 can also be applied to the embodiment described with reference to FIG. 4.

In one embodiment, the transparent-liquid supply source 55 (see FIG. 2) may be a chemical-liquid supply source, instead of the pure-water supply source. The transparent liquid is a transparent chemical liquid, instead of the pure water. An example of the chemical liquid is a potassium hydroxide (KOH) solution that has an etching effect.

When the chemical liquid is used as the transparent liquid, in order to prevent the chemical liquid from flowing onto the polishing pad 2 during polishing of the workpiece W, the light-emitting surface 71 and the light-receiving surface 72 of the optical sensor head 25 may be cleaned before or after polishing of the workpiece W.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing apparatus comprising:
a polishing table configured to support a polishing pad having a through-hole;
a polishing head configured to press a workpiece against the polishing pad;
an optical film-thickness measuring system having an optical sensor head mounted to the polishing table;
a transparent-liquid inlet passage configured to supply a transparent liquid to the through-hole; and
a light-emitting-side transparent-liquid outlet passage and a light-receiving-side transparent-liquid outlet passage communicating with the through-hole,
wherein the optical sensor head has a light-emitting surface configured to emit light obliquely upward and a light-receiving surface configured to receive reflected light from the workpiece, and
the light-emitting surface faces the light-emitting-side transparent-liquid outlet passage, and the light-receiving surface faces the light-receiving-side transparent-liquid outlet passage.

2. The polishing apparatus according to claim 1, wherein the light-emitting surface and the light-receiving surface face obliquely upward.

3. The polishing apparatus according to claim 1, wherein the light-emitting surface is located in the light-emitting-side transparent-liquid outlet passage, and the light-receiving surface is located in the light-receiving-side transparent-liquid outlet passage.

4. The polishing apparatus according to claim 1, wherein the transparent-liquid inlet passage is located between the light-emitting-side transparent-liquid outlet passage and the light-receiving-side transparent-liquid outlet passage.

5. The polishing apparatus according to claim 4, wherein the light-emitting-side transparent-liquid outlet passage and the light-receiving-side transparent-liquid outlet passage are arranged symmetrically with respect to the transparent-liquid inlet passage.

6. The polishing apparatus according to claim 1, wherein the transparent-liquid inlet passage is coupled to a transparent-liquid supply source which is a pure-water supply source or a chemical-liquid supply source.

7. The polishing apparatus according to claim 1, further comprising an ultrasonic vibrator configured to apply ultrasonic waves to the transparent liquid flowing through the transparent-liquid inlet passage.

8. The polishing apparatus according to claim 1, further comprising:
a flow-rate regulation valve coupled to the transparent-liquid inlet passage; and
an operation controller configured to control operation of the flow-rate regulation valve, the operation controller being configured to:
instruct the flow-rate regulation valve to supply the transparent liquid to the through-hole at a first flow rate when the workpiece is located over the through-hole during polishing of the workpiece; and
instruct the flow-rate regulation valve to supply the transparent liquid to the through-hole at a second flow rate lower than the first flow rate when the workpiece is not located over the through-hole during polishing of the workpiece.
